(19) United States
(12) Patent Application Publication
(10) Pub. No.: US 2025/0109476 A1
(43) Pub. Date: Apr. 3, 2025

(54) Method for Improved Heavy Metal Wetting on a Surface

(71) Applicant: UCHICAGO ARGONNE, LLC, Chicago, IL (US)

(72) Inventors: Sumit Bhattacharya, Darien, IL (US); Yinbin Miao, Naperville, IL (US); Nicolas E. Stauff, Oak Park, IL (US); Abdellatif M. Yacout, Naperville, IL (US)

(21) Appl. No.: 18/786,096

(22) Filed: Jul. 26, 2024

Related U.S. Application Data
(60) Provisional application No. 63/541,441, filed on Sep. 29, 2023.

(51) Int. Cl. C23C 2/08; C23C 2/02; C23C 14/06; C23C 14/18; C23C 14/34; C23C 14/58

(52) U.S. Cl. CPC C23C 2/08; C23C 2/0224; C23C 14/0635; C23C 14/18; C23C 14/3464; C23C 14/5806

(57) ABSTRACT

A method for coating a coolant metal on a ceramic substrate comprises modification of the substrate surface to provide an oxide free surface upon which the coolant metal is deposited.

### CROSS-REFERENCE TO RELATED APPLICATION

The benefit of priority to U.S. Provisional Patent Application No. 63/541,441 filed Sep. 29, 2023 is hereby claimed and the disclosure is incorporated herein by reference in its entirety.

### STATEMENT OF GOVERNMENT SUPPORT

This invention was made with government support under Contract No. DE-AC02-06CH11357 awarded by the United States Department of Energy to UChicago Argonne, LLC, operator of Argonne National Laboratory. The government has certain rights in the invention.

### FIELD

The disclosure relates to methods for modifying a ceramic substrate surface to improve coolant metal wetting of the ceramic surface, and more particularly wetting of coolant metals selected form Pb, Sn, and Pb—Bi eutectic alloys over ceramic substrates.

### BACKGROUND

Coolant metals such as Pb and Sn have been proposed a bonding materials between SiC cladding and graphite base materials to improve heat transfer for high temperature gas cooled nuclear microreactors. The liquid metal bond eliminates the large thermal resistance over the pre-closure gap that may be present if SiC is directly placed in contact with the graphite matrix. Current utilization of liquid metal bonds is problematic in having unfilled regions or voids. Conventional strategies for reducing these defects include reducing surface roughness, increasing application temperature, where the coolant metal either has low surface tension or chemically reacts to form an intermetallic compound leading to a reduction in the contact angle, or removal of the surface oxide layer, which requires special processing conditions to avoid exposure of the SiC surface to air. These conventional strategies, however, have not been successful in providing a defect free bonding layer, as it is nearly impossible to achieve a surface without any defects, such as micro-cavities or asperities. It is also extremely difficult to remove the surface oxide layer, as SiC naturally forms an oxide upon any exposure to ambient conditions. Finally, the operation temperature is fixed in many applications, thus, there is not much room for modification of the surface tension properties of molten Pb and Sn as a solution to the problem.

### SUMMARY

Methods of depositing a coolant metal on a SiC substrate in accordance with the disclosure can include co-depositing Al and SiC onto a surface of the SiC substrate to form a first layer; co-depositing Al and a metal onto the first layer to form a second layer, wherein the metal is the same as the coolant metal. The method further includes performing a two stage heating of the substrate having the first and second layers, wherein the first stage heating comprises heating to a first temperature of about 250° C. to about 600° C. and the second stage heating comprises heating to a second temperature of about 700° C. to about 1200° C. to thereby form an intermediate structure having (i) an intermediate layer between the first layer and the SiC substrate and (ii) an aluminum oxide layer on an exposed surface of the second layer, wherein the intermediate layer comprises aluminum carbide and silicon. The method further includes immersing the intermediate structure in a low oxygen molten metal bath comprising the coolant metal, under vacuum, thereby removing the aluminum oxide layer to expose the second layer, which then dissolves in the molten metal bath leaving an exposed surface comprising an admixture of aluminum carbide, silicon, and SiCₓ onto which the coolant metal deposits from the molten metal bath.

Methods of depositing a coolant metal on a ceramic substrate comprising a carbide or nitride of M, where M is a metal or a metalloid in accordance with the disclosure can include co-depositing Al and a carbide or nitride of M onto a surface of the ceramic substrate to form a first layer, wherein the carbide or nitride of M is the same as in the substrate; co-depositing Al and a metal onto the first layer to form a second layer, wherein the metal is the same as the coolant metal. The method further includes performing a two stage heating of the substrate having the first and second layers, wherein the first stage heating comprises heating to a first temperature of about 250° C. to about 600° C. and the second stage heating comprises heating to a second temperature of about 700° C. to about 1200° C. to thereby form an intermediate structure having (i) an intermediate layer between the first layer and the ceramic substrate and (ii) an aluminum oxide layer on an exposed surface of the second layer, wherein the intermediate layer comprises M and aluminum carbide or aluminum nitride. The method further includes immersing the intermediate structure in a low oxygen molten metal bath comprising the coolant metal, under vacuum, thereby removing the aluminum oxide layer to expose the second layer, which then dissolves in the molten metal bath leaving an exposed surface comprising an admixture of aluminum carbide or aluminum nitride, M, and a carbide or nitride of M onto which the coolant metal deposits from the molten metal bath.

In any of the methods of the disclosure, the coolant metal is a heavy metal with low vapor pressure at target operating temperatures of about 750° C. to about 900° C. For example, the coolant metal is Sn, Pb, or a Pb—Bi eutectic alloy.

In any of the methods of the disclosure, immersing the intermediate structure into the molten metal bath can include pre-forming a molten metal bath and immersing the intermediate structure therein. Alternatively, the intermediate structure can be mixed with solid coolant metal and then heated to a temperature above 700° C. to melt the solid coolant metal forming the molten metal bath and immersing the intermediate structure in situ with the melting process.

### BRIEF DESCRIPTION OF THE DRAWINGS

FIG. 1A is an SEM image of an as-received SiC surface.

FIG. 1B is an EDS spectrum of the SiC surface shown in FIG. 1A.

FIG. 1C is a table showing the elemental composition of the SiC surface shown in FIG. 1A.

FIG. 2A is an Ellingham diagram for Pb oxide stability verses SiOₓ, showing that any of the Pb oxide forms are not stable against SiOₓ formation.

FIG. 2B is an Ellingham diagram for Sn oxide stability verses SiOₓ, showing that any of the Sn oxide forms are not stable against SiOₓ formation.

FIG. 3 is a schematic illustration of a method in accordance with the disclosure.

FIG. 4 is an Al—Sn phase diagram, and the corresponding images of segregation of the heavier Sn to the bottom when the layer is exposed to high temperatures.

FIG. 5A is an image of an unmodified SiC disc and the corresponding graphite crucible recovered after it was exposed to 45 thermal cycles under Sn bath (Sn solid piece recovered is also shown).

FIG. 5B is a scanning electron microscope image of the unmodified disc of FIG. 5A.

FIG. 5C is a FIB cross-sectional image of the unmodified disc of FIG. 5A.

FIG. 5D is an EDS mapping of the surface shown in FIG. 5A, showing no Sn interaction with the SiC surface.

FIG. 6A is an image of a modified SiC disc, modified by a method in accordance with the disclosure, and the corresponding graphite crucible recovered after it was exposed to 45 thermal cycles under Sn bath (Sn solid piece recovered is also shown).

FIG. 6B is a scanning electron microscope image of the modified disc of FIG. 6A showing a uniform coating layer over the surface.

FIG. 6C is a FIB cross-sectional image of the unmodified disc of FIG. 6A showing a distinct layer of Sn on top of the SiC surface.

FIG. 6D is an EDS mapping of the surface shown in FIG. 6A, confirming the presence of the Sn layer and the surface modification layer (Al+SiC) on the top of the SiC disc.

### DETAILED DESCRIPTION

Methods of the disclosure provide for coating of a ceramic substrate surface with a coolant metal with wetting of the coolant metal layer onto the substrate surface due to removal and/or prevention of formation of an oxide surface at an interface between the coolant metal and the substrate. While disclosure here in is largely made with reference to SiC surfaces and Sn coolant metal, it should be understood that the method of the disclosure can be extended to other ceramic substrates that comprises a carbide or nitride of M, where M is a metal or a metalloid and other coolant metals including Pb and Pb—Bi eutectic alloys.

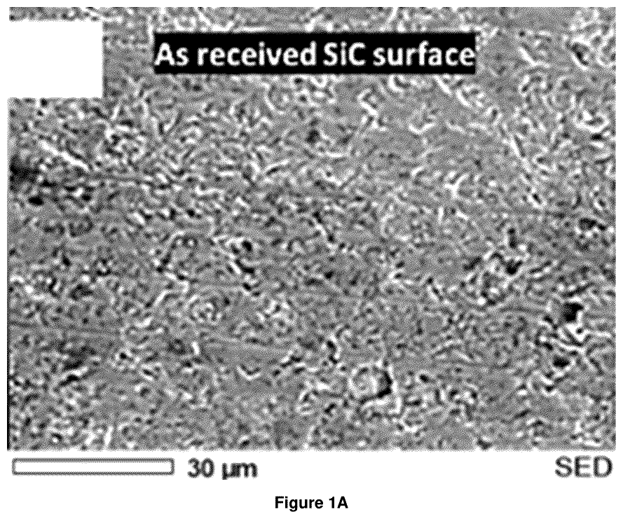

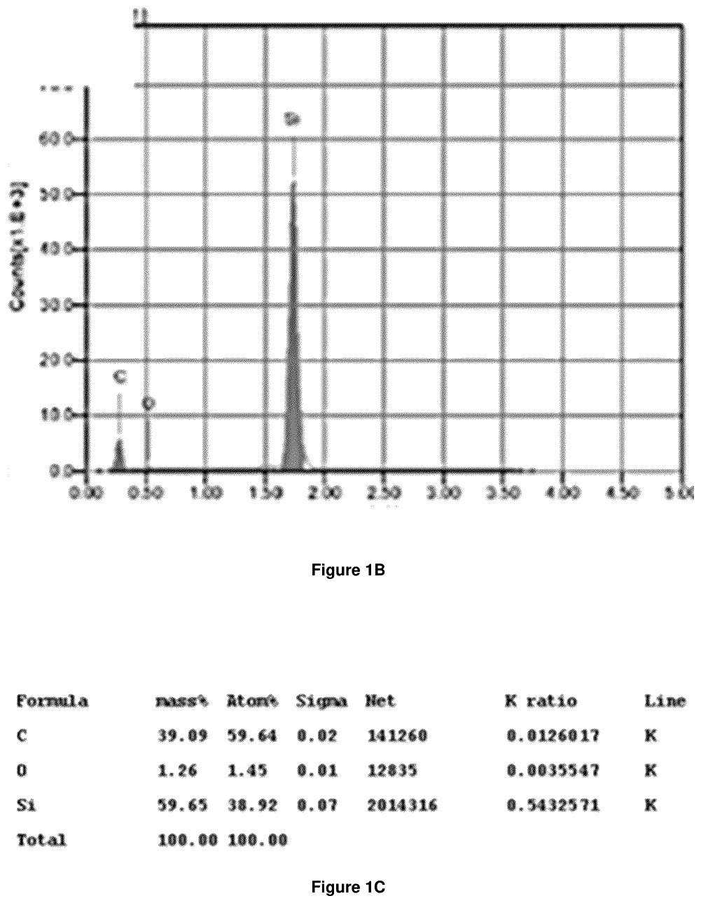

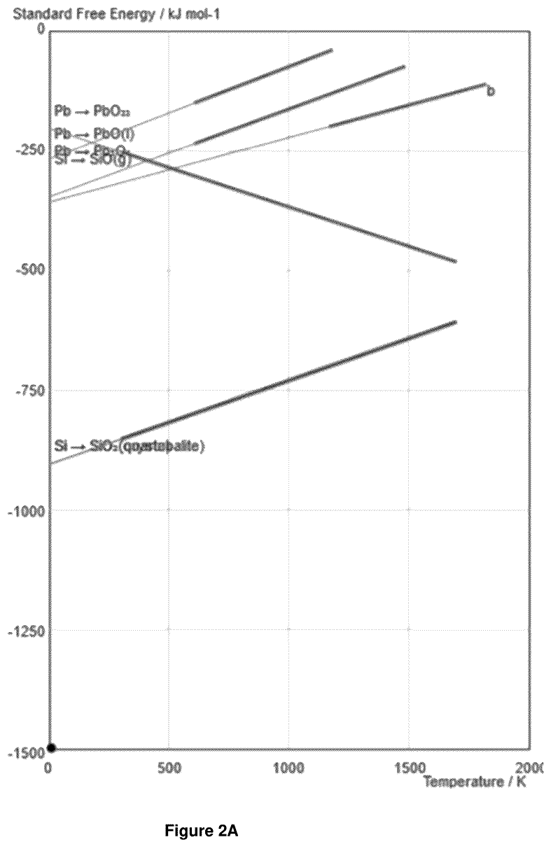

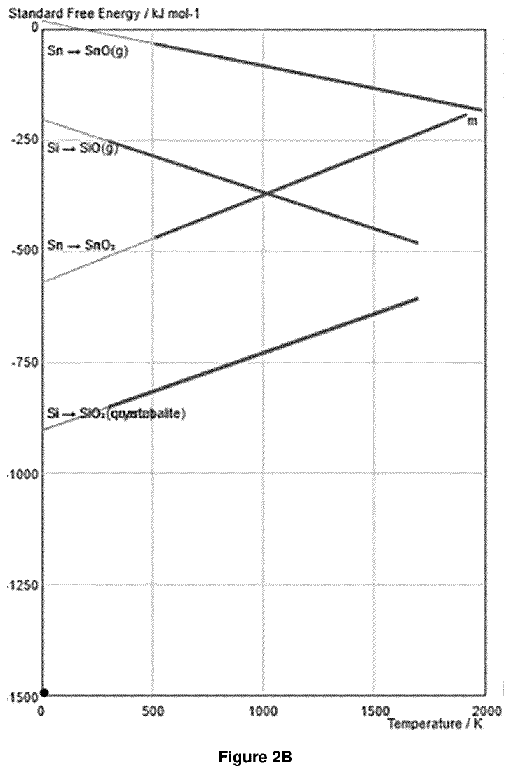

Ceramic surfaces such as SiC surfaces are susceptible to formation an oxide on the surface when exposed to atmosphere. It has been observed that the wettability problems of coolant metals on ceramic surfaces results from the presence of this oxide layer. FIG. 1A is an SEM image of an as-received SiC disc surface. Based on the EDS studies shown in FIG. 1B, it was found that the surface had about 1.3 wt % oxide. This amorphous, naturally formed SiO₂ layer present on SiC surfaces was found to impede the wettability of coolant metals on the SiC surface. Referring to FIGS. 2A and 2B, a representative Ellingham diagram for Sn and Pb oxides verses silicon oxide shows why purse Pb and Sn cannot form any interaction or wet the surface of SiC, which has a thin layer of oxide present on the surface. Both Pb and Sn, any oxides thereof are not stable against SiOₓ formation. Thus, at all operational temperature molten Pb and molten Sn cannot interact with the SiC surface. As a result, the application of a coolant metal to fill the gap between a SiC and graphite surface at atmospheric pressure leaves unfilled regions or voids in the bond, particularly in rough and uneven locations. These voids lead to undesirable local hot spots, which can develop local stress concentration of the SiC surface resulting in micro cracks and ultimately failure of the structure.

Methods of the disclosure beneficially provide a surface modification over the ceramic surface that will provide an oxide-free surface that is contact with the molten metal and thereby improve wetting of the surface with a coolant metal and prevent voids or cavities in the bonding layer that can lead to hot spot formulation.

The method will be described in detail with reference to FIG. 1, which illustrates the method in the context of a SiC substrate and deposition of Sn as the coolant metal. This method is extendible to other ceramic substrates comprising a carbide or nitride of M, where M is a metal or metalloid. M can be for example, silicon or boron. For example, the substrate can be silicon nitride, silicon carbide, boron nitride, or boron carbide. Similarly, the method is extendible to any coolant metal selected from Pb, Sn, and an Pb—Bi eutectic alloy.

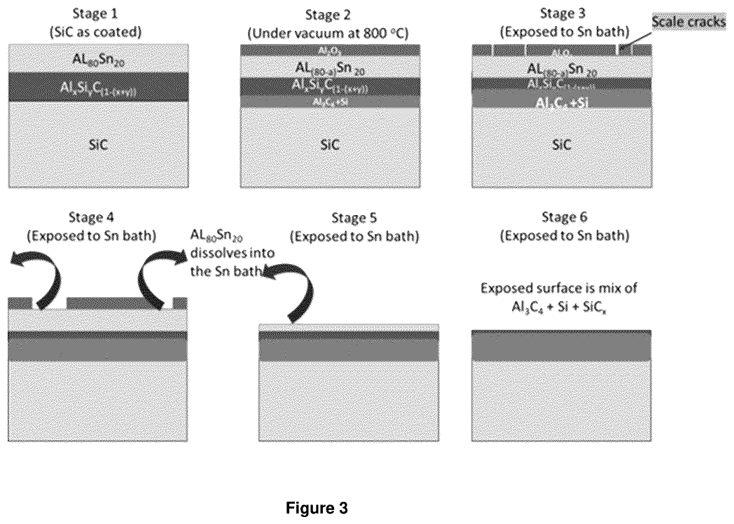

Referring to FIG. 3, methods of the disclosure can include co-depositing Al and SiC onto the SiC substrate forming a first layer. Deposition of the first layer onto the SiC substrate results in removal of silica present on the SiC surface due to exposure to of the SiC substrate to atmosphere. The Al present in the first layer reduces silica to Si and further interacts with SiC to form carbide. The co-deposition of Al with SiC helps to reduce the rate of Al interaction with the substrate, as the SiC substrate will interact with Al. This is extendible to substrates other than SiC, in which the co-deposition to form the first layer is made with Al and the same carbide or nitride of M as present in the substrate. As with the SiC substrate, the Al present in the first layer reduces the oxide of M present on the surface to M and further interacts with the carbide or nitride of M to form a carbide or nitride.

The aluminum and carbide or nitride of M, for example SiC, can be co-deposited, for example, by physical vapor deposition.

The first layer can have a thickness of about 0.1 μm to about 10 μm.

Referring still to FIG. 3, Al and a metal that is the same as the coolant metal are then co-deposited on the first layer to form a second layer. Sn is shown in the example of FIG. 3 by way of illustration only. The second layer serves as a protective layer to the first layer. Al is very sensitive to oxygen and oxidation of the first layer can make it difficult to expose a pure metal carbide surface. The second layer, therefore, is provided as a low melting sacrificial alloy which itself oxidizes while preventing the first layer from oxidation.

The Al and metal of the second layer, which is the same as the coolant metal, can be co-deposited by sputtering onto the first layer to form the second layer.

The second layer can have a thickness of about 0.1 μm to about 10 μm.

The resulting structure is then subjected to a heating process, which results an intermediate structure having an intermediate layer formed between the first layer and the substrate and an aluminum oxide formed on an exposed surface of the second layer. During heating, the interaction of the first layer and the ceramic substrate results in an intermediate layer being formed between the first layer and the substrate, the intermediate layer comprising aluminum carbide or aluminum nitride and the metal or metalloid M of the substrate (aluminum carbide and silicon being shown in the intermediate layer of the example illustrated in FIG. 3). The second-stage higher temperature heating of substrates results in the metal present in the second layer (Sn being shown by way of example) sinking beneath the light Al, thereby exposing Al to the surface, and allowing an aluminum oxide coating to form on the exposed surface of the second layer as a protective oxide layer. The heating process can include heating the substrate having the first and second layers under vacuum in one or both of the first and second stages of heating.

The heating process can be, for example, a two-stage heating process in which the substrate is heated in the first stage to a first temperature of about 250° C. to about 600° C. and then heated in the second stage to a second temperature of about 700° C. to about 1200° C. The substrate can be held at the first and second temperatures, respectively, during each heating stage for a hold time independently selected from 15 to 30 min for the first stage and about 1 hour to about 20 hours for the second stage. For example, the second sage can be about 10 hours.

Alternatively, the heating process can be a single stage during which the substrate is heated to a temperature of about 700° C. to about 1200° C. The single-stage heating process can include holding the substrate at the temperature for about 1 hour to about 20 hours. For example, the substrate can be held at the temperature for about 10 hours. For example, the single stage heating process can include a temperature ramping to the final hold temperature that is done in the presence of the substrate. The substrate passes through a lower temperature range while the temperature is being ramped to the final hold temperature. The ramp rate can be selected depending on a duration of time at which the substrate is desired to be subject to a lower temperature range. For example, the ramp rate can be selected such that the substrate is exposed to a temperature range of about 250° C. to about 600° C. for about 15 to 30 mins.

The intermediate structure is then immersed in a low oxygen molten metal bath comprising the coolant metal under vacuum and held for a time sufficient to allow the aluminum oxide layer broken down, for example, by cracking, thereby exposing the second layer, which then dissolves in the molten bath leaving a surface comprising an admixture of aluminum carbide, silicon (or other M of the substrate), and SiCₓ (or other carbide or nitride of M used in the second layer) onto which the coolant metal of the molten bath deposits. The method advantageously provides a surface free of oxide that is exposed to the molten metal bath, which allows for formation of a uniform wetted layer over the substrate surface.

The coolant metal can be preheated to form the molten metal bath into which the substrate having the intermediate layer is immersed. Alternatively, the immersion can happen in situ with a melting process to form the molten metal bath. For example, the intermediate structure can be combined with solid coolant metal and the combination can be heated to a temperature sufficient to melt the coolant metal, thereby forming the molten metal bath and immersing the intermediate structure therein in situ with the melting of the coolant metal. The heating temperature for forming the molten metal bath can be, for example, about 700° C. For example, the heating temperature for forming the molten metal bath can be about 700° C. to about 900° C. In any of the immersing processes, the intermediate structure can be retained in the molten metal bath for about 30 mins to about 45 min.

### EXAMPLES

SiC discs were coated in accordance with disclosure with Sn coolant metal and compared to unmodified SiC discs. The SiC discs in accordance with the disclosure were formed by co-depositing a layer of Al and SiC with physical vapor deposition process to form a first layer having a thickness of about 200 nm. The SiC was deposited using a radio frequency (RF) power source and the Al was deposited with a DC power source. The power density applied for the SiC and Al targets were 20 W/in² and 50 W/in², respectively. This was followed by co-deposition of Al and Sn to form a second layer having a thickness of about 500 nm. Al and Sn were both sputtered using DC power source. The power density applied to the Al and Sn targets were 50 W/in² and 30 W/in² respectively. The substrate having the first and second layers were then subjected to a two-stage heating process in which the first stage heating was performed at a temperature of 500° C. and the second stage heating was performed at a temperature of about 800° C. The heating was performed under vacuum, with the substrate being held at the second stage for 10 hours under vacuum.

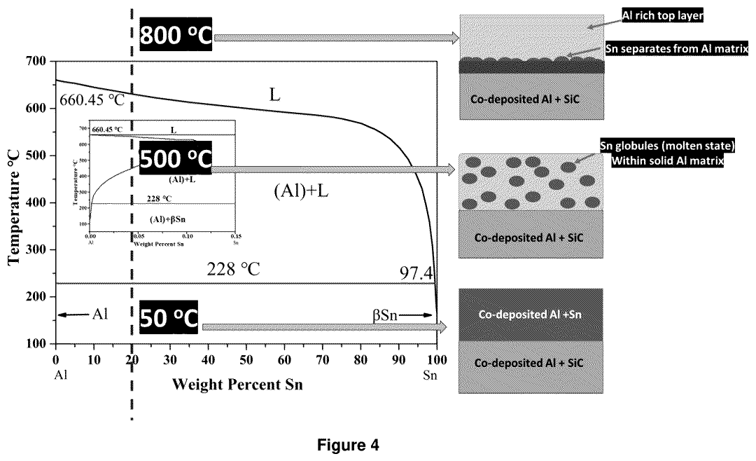

FIG. 4 is an Al—Sn phase diagram and corresponding segregation of heavier Sn to the bottom of a layer upon exposed to higher temperatures. The heating process is believed to result in Sn settling beneath the lighter Al layer when heating at the second stage heating temperature, thereby providing a segregation of Sn and Al within the second layer, and concentrating Al on the exposed surface of the second layer, thereby allowing for formation of an aluminum oxide layer on the exposed surface of the second layer, while protecting an interface between the substrate and the first layer from oxidation.

After heating, the intermediate structure was combined with solid pellets of Sn and the combination was heated to a temperature of 850° C. to melt the solid pellets of Sn and form the molten metal bath and immerse the substrate in the molten metal bath in situ with the melting process. The molten metal bath was held at 850° C. under vacuum while the intermediate structure was immersed therein. The high temperature exposure broke the surface aluminum oxide scale exposing the low melting Al—Sn alloy of the second layer. The second layer once exposed dissolves into the molting metal bath, thereby exposing a surface containing Al₃C₄, SiC, and Si to the molten metal bath. Significantly, this exposed surface was oxide free, thereby allowing the coolant metal from the molten metal bath to form a uniform wetted layer over the SiC surface.

A thermal study was conducted to evaluate Sn coating of a disc modified with the first and second layers and the two stage heating process in accordance with the disclosure to form the intermediate structure (modified SiC disc) as compared an unmodified SiC disc. The modified SiC disc and unmodified disc were loaded inside a sealed metal container. Both discs were submerged in a low O₂ Sn bath and exposed to continuous thermal cycling in which for each cycle the temperature was raised to 850° C. and lowered to room temperature. 45 thermal cycles were performed, where the sample stayed at 850° C. for 5 hours per cycle and the temperature cycling was maintained for 7 continuous days.

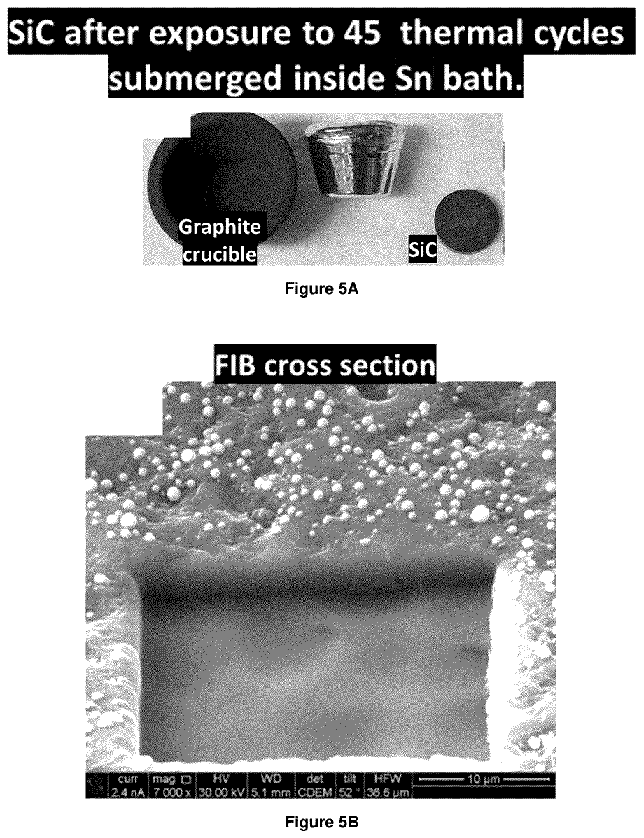

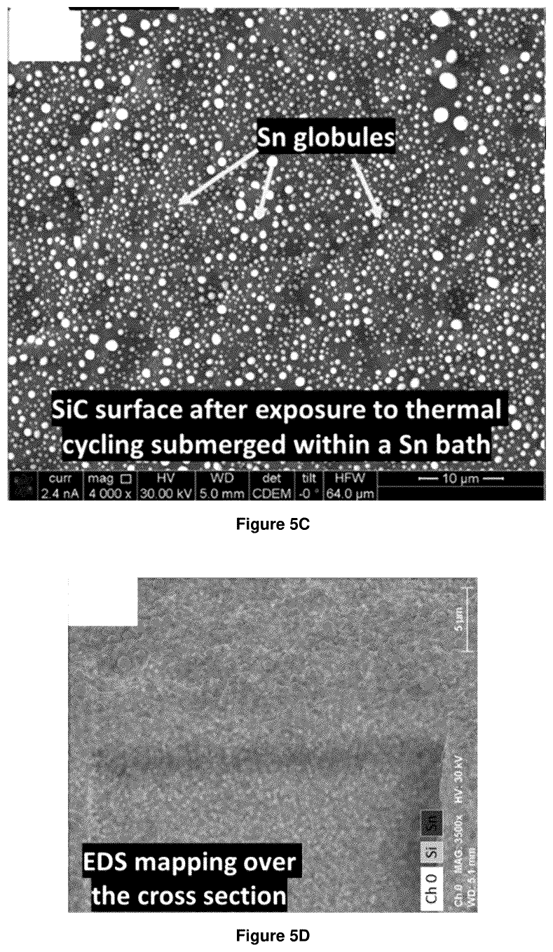

FIG. 5A illustrates the unmodified SiC disc and corresponding graphite crucible recovered at exposure to 45 thermal cycles immersed in the Sn bath, along with a solid piece of Sn recovered. FIG. 5B is a scanning electron microscope image of the unmodified SiC surface after immersion in the Sn bath, showing white metallic particles distributed all over the surface. FIG. 5C is a corresponding FIB cross-section image of the unmodified disc shown in FIG. 5B. FIG. 5D shows the collected EDS mapping of the surface, illustrating that there was Sn interaction with the SiC surface after immersion of the unmodified disc in the Sn molten bath.

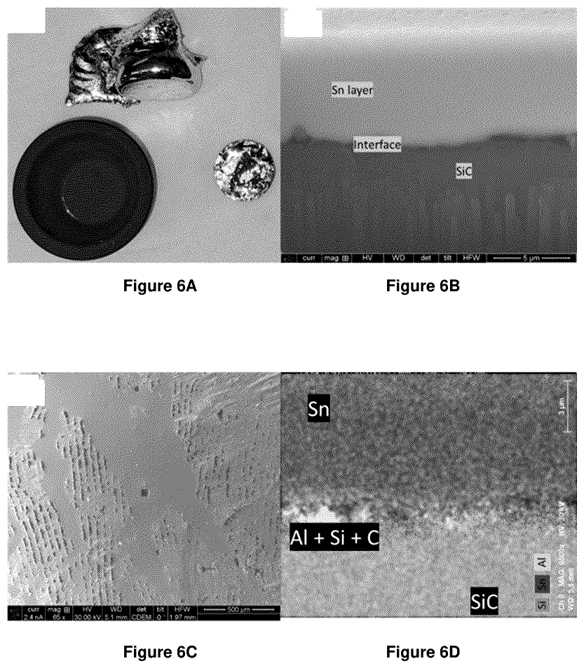

By comparison, FIG. 6A illustrates the modified SiC disc and corresponding graphite crucible recovered at exposure to 45 thermal cycles immersed in the Sn bath, along with a solid piece of Sn recovered. FIG. 6B is a scanning electron microscope image of the modified SiC surface after immersion in the Sn bath, showing a uniform layer coving the surface. FIG. 6C is a corresponding FIB cross-section image of the unmodified disc shown in FIG. 6B showing a distinct Sn layer on top of the SiC surface. FIG. 5D shows the collected EDS mapping of the surface, confirming the Sn layer and the surface modification layer (Al+SiC) present on the top of the SiC disc.

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

1. A method of depositing a coolant metal on a SiC substrate, comprising:
co-depositing Al and SiC onto a surface of the SiC substrate to form a first layer;
co-depositing Al and a metal onto the first layer to form a second layer, wherein the metal is the same as the coolant metal;
exposing the substrate having the first and second layers to a two-stage heating comprising a first stage in which the substrate is heated to a first temperature of 250° C. to 600° C. and a second stage in which the substrate is heated to a second temperature of 700° C. to 1200° C. to thereby form an intermediate structure comprising (i) an intermediate layer between the first layer and the SiC substrate and (ii) an aluminum oxide layer on an exposed surface of the second layer, wherein the intermediate layer comprises aluminum carbide and silicon; and
immersing the intermediate structure in a low oxygen molten metal bath comprising the coolant metal, under vacuum, thereby removing the aluminum oxide layer to expose the second layer, which then dissolves in the molten metal bath leaving an exposed surface comprising an admixture of aluminum carbide, silicon and SiCₓ onto which the coolant metal is deposited from the molten metal bath,
wherein the coolant metal comprises Sn, Pb, or Pb—Bi eutectic alloy.

2. The method of claim 1, wherein immersing the intermediate structure in the molten metal bath comprises combining the intermediate structure with solid coolant metal and heating the combination to a temperature to melt the solid coolant metal thereby forming the molten metal bath and immersing the substrate in the molten metal bath.

3. (canceled)

4. The method of claim 2, wherein the combination is heated to a temperature of 700° C. to 900° C.

5. (canceled)

6. (canceled)

7. (canceled)

8. (canceled)

9. (canceled)

10. (canceled)

11. A method of depositing a coolant metal on a ceramic substrate comprising a carbide or nitride of M, where M is a metal or metalloid, comprising:
co-depositing Al and a carbide or nitride of M to form a first layer, wherein the carbide or nitride of M is the same carbide or nitride of M as in the substrate;
co-depositing Al and a metal onto the first layer to form a second layer, wherein the metal is the same as the coolant metal to be deposited;
exposing the substrate having the first and second layers to a two-stage heating comprising a first stage in which the substrate is heated to a first temperature of 250° C. to 600° C. and a second stage in which the substrate is heated to a second temperature of 700° C. to 1200° C. to thereby form thereby form an intermediate structure comprising (i) an intermediate layer between the first layer and the substrate and (ii) an aluminum oxide layer on an exposed surface of the second layer, wherein the intermediate layer comprises M and aluminum carbide or aluminum nitride; and
immersing the intermediate structure in a low oxygen molten metal bath comprising the coolant metal under vacuum, thereby removing the aluminum oxide layer to expose the second layer, which then dissolves in the molten metal bath leaving an exposed surface comprising an admixture of aluminum carbide, M, and a nitride or carbide of M onto which the coolant metal is deposited from the molten metal bath,
wherein the coolant metal is Pb, Sn, or a Pb—Bi eutectic alloy.

12. The method of claim 11, wherein immersing the intermediate structure in the molten metal bath comprises combining the intermediate structure with solid coolant metal and heating the combination to a temperature to melt the solid coolant metal thereby forming the molten metal bath and immersing the intermediate structure in the molten metal bath.

13. The method of claim 12, wherein the combination is heated to a temperature of at least 700° C.

14. The method of claim 13, wherein the combination is heated to a temperature of 700° C. to 900° C.

15. The method of claim 11, comprising holding the intermediate structure in the molten metal bath for a time of 30 min to 45 min.

16. The method of claim 11, wherein immersing the intermediate structure is performed in an inert atmosphere.

17. The method of claim 11, wherein the ceramic substrate is susceptible to oxide formation at atmospheric conditions.

18. The method of claim 11, wherein M is silicon or boron.

19. The method of claim 11, wherein the substrate is boron nitride, boron carbide, silicon carbide, or silicon nitride.

20. The method of claim 11, wherein the Al and the carbide or nitride of M are co-deposited by physical vapor deposition.

21. The method of claim 11, wherein the first layer and/or second layer has a thickness of 0.1 μm to 10 μm.

22. The method of claim 11, wherein Al and the metal are sputtered onto the first layer to form the second layer.

23. The method of claim 11, wherein the two-stage heating of the substrate having the first and second layers is performed under vacuum.

24. The method of any one of the preceding claims-claim 11, wherein the intermediate structure is held in the molten metal bath for 30 minutes to 45 minutes.

25. (canceled)

26. A method of depositing a coolant metal on a ceramic substrate comprising a carbide or nitride of M, where M is a metal or metalloid, comprising:
co-depositing Al and a carbide or nitride of M to form a first layer, wherein the carbide or nitride of M is the same carbide or nitride of M as in the substrate;
co-depositing Al and a metal onto the first layer to form a second layer, wherein the metal is the same as the coolant metal to be deposited;
exposing the substrate having the first and second layers to a heating process comprising holding the substrate at a hold temperature of 700° C. to 1200° C. to thereby form an intermediate structure comprising (i) an intermediate layer between the first layer and the substrate and (ii) an aluminum oxide layer on an exposed surface of the second layer, wherein the intermediate layer comprises M and aluminum carbide or aluminum nitride; and
immersing the intermediate structure in a low oxygen molten metal bath comprising the coolant metal under vacuum, thereby removing the aluminum oxide layer to expose the second layer, which then dissolves in the molten metal bath leaving an exposed surface comprising an admixture of aluminum carbide, M, and a nitride or carbide of M onto which the coolant metal is deposited from the molten metal bath,
wherein the coolant metal is Pb, Sn, or a Pb—Bi eutectic alloy.

27. The method of claim 26, wherein the heating process comprises ramping the temperature up from a first temperature to the hold temperature in the presence of the substrate and at a ramp rate selected such that the substrate is exposed to temperatures in the range of 250° C. to 600° C. for about 15 to 30 min during ramping.

28. The method of claim 26, wherein the carbide or nitride of M is SiC and the ceramic substrate is a SiC substrate.
